(19) United States
(12) Patent Application Publication
(10) Pub. No.: US 2021/0296280 A1
(43) Pub. Date: Sep. 23, 2021

(54) STACKED MODULE PACKAGE INTERCONNECT STRUCTURE WITH FLEX CABLE

(71) Applicant: QUALCOMM Incorporated, San Diego, CA (US)

(72) Inventors: Aniket PATIL, San Diego, CA (US); Hong Bok WE, San Diego, CA (US); Brigham NAVAJA, San Diego, CA (US)

(21) Appl. No.: 16/824,811

(22) Filed: Mar. 20, 2020

(51) Int. Cl. H01L 23/00

(52) U.S. Cl. CPC H01L 24/73; H01L 24/16; H01L 2224/73211; H01L 2224/16145; H01L 2224/16225; H01L 24/50

(57) ABSTRACT

Certain aspects of the present disclosure provide apparatus and techniques for connecting packages for integrated circuits or packaged assemblies with other packages or modules using flex cables. An example packaged assembly for integrated circuits includes: a first integrated circuit (IC) package, a second IC package disposed above the first IC package, and a flex cable, wherein an end of the flex cable is connected to at least one of the first IC package or the second IC package.

### BACKGROUND

### Field of the Disclosure

Aspects of the present disclosure relate to integrated circuits, and more particularly, to apparatus and techniques for connecting packages for integrated circuits or packaged assemblies with other packages or modules using flex cables.

### Description of Related Art

Electronic devices, such as computers, wireless communications devices (e.g., cellular phones and Wi-Fi access points), and calculators, have come into widespread use in recent years. The electronic devices typically include one or more integrated circuits (ICs). These ICs are typically included in one or more dies and other electronic components, which may be included in an IC package for assembly on a printed circuit board (PCB) and included in an electronic device.

Packaging integrated circuit dies and other components together in modules (also referred to herein as “packaged assemblies”) may enable electronic devices to have a smaller form factor while providing improved electrical performance (e.g., reduced power consumption) and thermal performance (e.g., reduced heat generation), as compared to previously known electronic devices. For example, a cellular phone may have improved battery life due to a reduction in power consumed by a transceiver module in which dies and other components are assembled in a packaged assembly.

Packaged assemblies may be mounted on top of each other in electronic devices. For example, a power management module packaged assembly and a memory module packaged assembly may be mounted on top of a baseband module packaged assembly. Power is typically supplied to higher packaged assemblies by routing the power from a power supply through a PCB and through one or more pins into the bottom packaged assembly. From the bottom packaged assembly, the power is supplied to upper packaged assemblies. Some signals may also be routed from the PCB through the bottom packaged assembly into upper packaged assemblies.

### SUMMARY

The methods and assemblies of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include smaller sizes (form factors) of packages or modules and/or reductions in power and/or signal transmission losses to packages disposed above other packages.

Certain aspects of the present disclosure provide a method for fabricating a packaged assembly for integrated circuits. The method generally includes disposing a second integrated circuit (IC) package above a first IC package and connecting an end of a flex cable to at least one of the first IC package or the second IC package.

Certain aspects of the present disclosure provide a packaged assembly for integrated circuits. The packaged assembly generally includes a first integrated circuit (IC) package; a second IC package disposed above the first IC package; and a flex cable, wherein an end of the flex cable is connected to at least one of the first IC package or the second IC package.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 is a side view of an exemplary board assembly, in accordance with certain previously known aspects of the present disclosure.

FIG. 2 is a side view of an exemplary board assembly with a flex cable, in accordance with certain aspects of the present disclosure.

FIGS. 3A-D illustrate an exemplary process flow for manufacturing packaged assemblies with flex cables, in accordance with certain aspects of the present disclosure.

FIG. 4 is a flow diagram illustrating example operations for fabricating a packaged assembly, in accordance with certain aspects of the present disclosure.

FIGS. 5A and 5B are side views of exemplary packaged assemblies each having a flex cable connecting with a top of an integrated circuit package, in accordance with certain aspects of the present disclosure.

FIG. 6 is a side view of an exemplary packaged assembly having a flex cable attached to a side of an integrated circuit package, in accordance with aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Aspects of the present disclosure provide apparatus and methods for connecting packages for integrated circuits or packaged assemblies (e.g., wireless communication modules) with other packages or modules (e.g., power supplies) using flex cables.

The following description provides examples of using flex cables to connect packages for integrated circuits or packaged assemblies with other packages or modules, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

Previously known techniques for assembling packages on printed circuit boards (PCBs) use a bottom package substrate to route battery power, other power, and/or some signals (e.g., input/output (TO) signals) coming from board connectors on the PCB through a bottom package (e.g., through one or more connectors connecting the bottom package to traces on the PCB) and through a connector on top of the bottom package into another package mounted on the bottom package. Ultimately, the power and/or signals may be routed to a top module or package in a stack of modules or packages. This technique uses pads of the PCB and corresponding pins of the bottom module or package, appropriates routing space on the PCB and/or in the bottom module or package, and increases the footprint of the bottom module or package. In addition, power losses and signal degradations occur due to the power and signals passing through multiple transitions via interconnections between layers, substrates, and packages. The previously described technique also results in a relatively long path for routing power and signals to packages.

Using a flex cable to route power or signals from main PCB connectors (or the top or lateral surface of a module or package on the PCB) to a higher (e.g., top) package without using pins or substrate floorplan space of a bottom package reduces module solution footprint significantly. Therefore, usage of a flex cable can reduce a packaged system form factor by 10-20%. In addition, usage of a flex cable may provide better electrical connectivity (e.g., lowered impedance), because the flex cable provides a shorter route path and reduces a number of interconnect transitions in a packaged system.

In aspects of the present disclosure, a packaged assembly includes a first integrated circuit (IC) package, a second IC package above the first IC package, and a flex cable with one end connected to at least one of the first IC package or the second IC package. The flex cable supplies power and/or signals to the second IC package without the power and/or signals passing through the first IC package from a PCB to the second IC package.

According to aspects of the present disclosure, a flex cable may be used in delivering power and/or signals to a stacked package or module solution that uses interconnections directly from a main PCB to a top package without requiring an interconnect through the bottom package of the stacked package. For example, dynamic random access memory (DRAM) in a package-on-package (PoP) module may obtain power from a PCB without the power passing through lower packages of the PoP module. In another example, a flex cable may convey power from a battery (e.g., from connectors of a board battery connector) to a top module (e.g., a power management module) in a stacked module assembly. Aspects of the present disclosure may be used with any package-on-package (PoP), module-on-module, package-on-module, or module-on-package stacked solution.

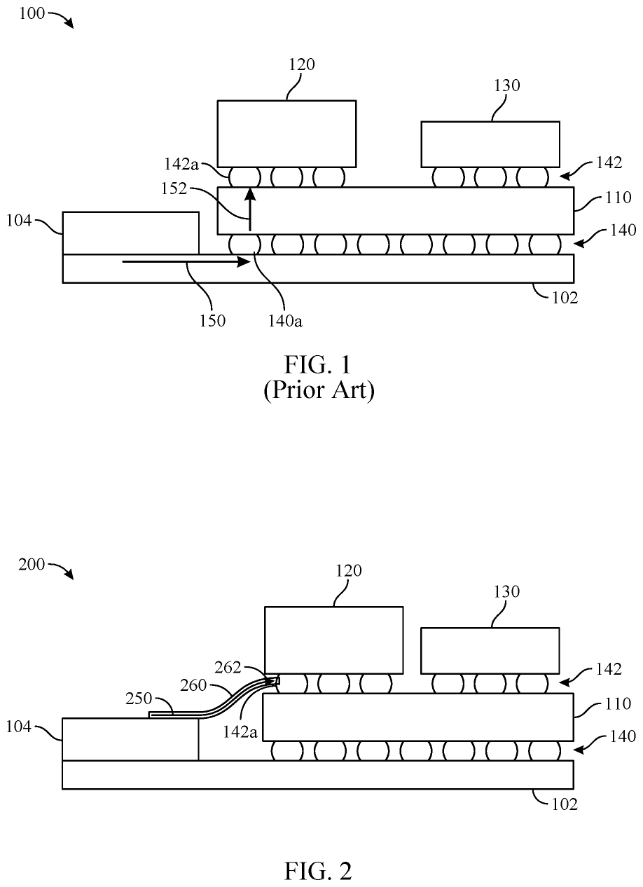

FIG. 1 is a side view of an exemplary board assembly 100, in accordance with certain previously known aspects of the present disclosure. The board assembly 100 includes a PCB 102, a battery connector 104, a first integrated circuit (IC) package 110 (e.g., a baseband module), a second IC package 120 (e.g., a power management module), zero or more other IC packages 130 (e.g., a memory module), and pins of the exemplary IC packages 110, 120, and 130. The pins may be implemented as a ball grid array (BGA) of solder balls 140 and 142.

As illustrated in FIG. 1, electric power 150 from the battery connector 104 flows through one or more pads on the PCB 102 to one or more pins (e.g., pin 140a) and into the first IC package 110. Electric power 152 in the first IC package 110 is supplied through a pin 142a to the second IC package 120. While the previously known technique is illustrated with electric power from a battery connector, the previously known technique may also be used for supplying electric power to the second IC package from a power supply other than a battery. Also, the previously known technique may be used to supply one or more signals from one or more other packages (e.g., at other locations on the PCB 102) through the first IC package 110 to the second IC package 120.

### Example Stacked Module Package Interconnect Structure with Flex Cable

FIG. 2 is a side view of an exemplary board assembly 200, in accordance with certain aspects of the present disclosure. The board assembly 200 includes several components that are illustrated in the board assembly 100 and are not further described in FIG. 2. The exemplary board assembly 200 includes a flex cable 260, with one end 262 of the flex cable connected to at least one of the first IC package 110 and the second IC package 120.

As illustrated in FIG. 2, electric power 250 from the battery connector 104 flows through the flex cable 260 to a pin 142a and into at least one of the first IC package 110 and the second IC package 120. While FIG. 2 illustrates aspects of the present disclosure with electric power from a battery connector, the present disclosure is not so limited. According to aspects of the present disclosure, the flex cable 260 may also be used for supplying electric power to the first IC package and/or the second IC package from a power supply other than a battery. Also, the flex cable 260 may be used to supply one or more signals from one or more other packages (e.g., at other locations on the PCB 102) to the first IC package and/or the second IC package.

According to aspects of the present disclosure, the flex cable may include one or more conductors (e.g., copper (Cu) conductors), which may be laminated on a first side of a flexible base layer. The base layer may be made of, for example, pre-impregnated composite fibers that may be referred to as flexible “prepreg” or flex PPG. The conductors and the first side of the base layer may be coated with a first layer of adhesive. Similarly, the second side of the base layer may also be coated with a second layer of adhesive. A first layer of coverlay material (e.g., silicone rubber or polyvinyl chloride) may be disposed on and adhere to the first layer of adhesive, and a second layer of coverlay material may be disposed on and adhere to the second layer of adhesive. The flex cable may then be cut or punched to a desired length. Ends of the conductors are exposed to enable the conductors to be electrically conductively connected to other conductors (e.g., SOP pads on an IC package or pins of a battery connector). The ends of the conductors may be exposed, for example, by a cutting process, or by preventing the first layer of adhesive and first layer of coverlay material from covering the ends of the conductors.

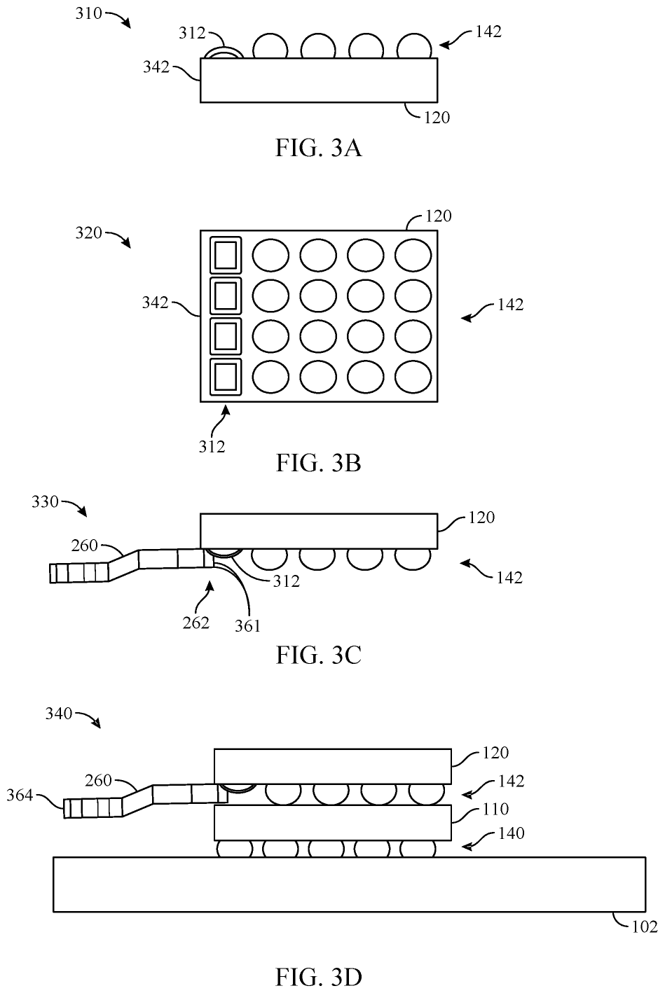

FIGS. 3A-D schematically illustrate an exemplary process flow for manufacturing packaged assemblies with flex cables, in accordance with certain aspects of the present disclosure. The exemplary process flow involves certain items shown in FIGS. 1 and 2 that are not further described. FIG. 3A depicts a first side view of a second IC package 120, and FIG. 3B depicts a top view of the second IC package 120 (before inversion). The exemplary process flow begins at 310 and 320 in FIGS. 3A and 3B by arranging a BGA of solder balls 142 and a group of solder on pad (SOP) pads 312 on a second IC package 120. As shown, the group of SOP pads is arranged at or near an edge 342 of the second IC package. Although four SOP pads 312 are depicted in FIG. 3B, more or less than four SOP pads may be used for connections to a flex cable. Moreover, although the four SOP pads 312 are disposed in a single column at one edge of the second IC package 120 in FIG. 3B, the present disclosure is not so limited. The SOP pads 312 may be arranged in one or more columns, one or more rows, or some combination thereof (e.g., arranged as a square in a corner occupying portions of two rows and two columns). Furthermore, aspects of the present disclosure are not limited to SOP pads, and any of various other suitable electrically conductive structures for connecting to a flex cable may be employed.

Next, at 330 in FIG. 3C, one end 262 of the flex cable 260 is attached to the SOP pads 312 of the second IC package 120. FIG. 3C depicts a second side view of the second IC package 120, after inverting the workpiece with the flex cable attached to the second IC package. That is, the second IC package 120 is flipped in FIG. 3C when compared to FIG. 3A. The end of the flex cable 260 may be attached to the second IC package using a hot bar or tape-automated bonding (TAB) technique, which involves heating and applying pressure to the end of the cable and the SOP pads. For example, as illustrated in FIG. 3C, tape-automated bonds (TABs) 361 on the end 262 of the flex cable may be used to connect with the second IC package. At 340 in FIG. 3D, the workpiece may be mounted to a first IC package 110, which may involve, for example, using a solder reflow process to electrically connect the second IC package to the first IC package via the solder balls 142 in the BGA. As shown in FIG. 3D, the first IC package may already be mounted to the PCB 102, but the present disclosure is not so limited, and the combination of the second IC package, the first IC package, and the flex cable may be mounted to the PCB after the workpiece is connected to the first IC package. The other end 364 of the flex cable is shown as being unconnected, but the present disclosure is not so limited. In aspects of the present disclosure, the other end of the flex cable may be connected to a connector (e.g., battery connector 104, shown in FIG. 1) on the PCB before, during, or after the workpiece is mounted to the first IC package. Alternatively, the other end 364 of the flex cable may be connected to a connector on the PCB before during, or after the first IC package is mounted to the PCB.

In aspects of the present disclosure, the end of the flex cable may be connected to the second IC package via a plurality of electrically conductive connections. The flex cable may not be directly conductively connected to the first IC package in the packaged assembly (see, e.g., end 262, second IC package 120, SOP pads 312, and first IC package 110 in FIGS. 3A-D, above).

According to aspects of the present disclosure, the end of the flex cable may connect to the second IC package via a plurality of solder on pad (SOP) pads of the second IC package, the flex cable may not be directly conductively connected to the first IC package, and the first IC package may be connected to the second IC package via a plurality of electrically conductive connections formed from a plurality of solder balls implemented as a ball grid array (BGA) (see, e.g., flex cable 260, SOP pads 312, second IC package 120, first IC package 110, and solder balls 142 described with reference to FIGS. 3A-D, above).

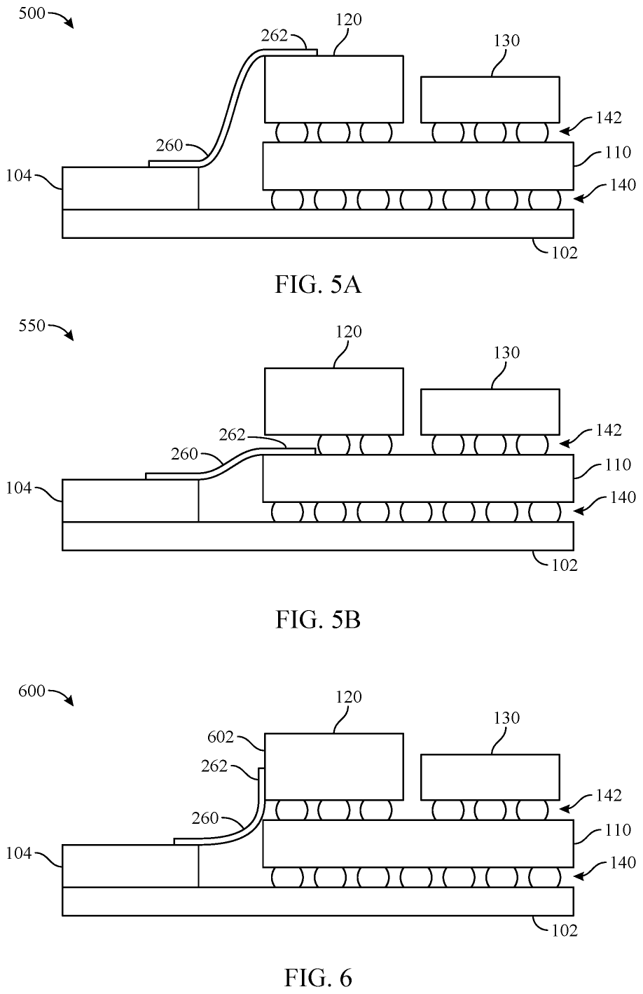

According to aspects of the present disclosure, the flex cable may connect to a first side of the second IC package. In this case, a second side of the second IC package may be nearer to the first IC package than the first side is to the first IC package (see, e.g., end 262 of flex cable 260, second IC package 120, and first IC package 110 described with reference to FIG. 5A, below). For example, the flex cable may connect to the top of the second IC package, which is disposed above the first IC package, such that the bottom of the second IC package is nearer to the first IC package than the top of the second IC package.

According to aspects of the present disclosure, the end of the flex cable may be connected to the second IC package via hot bar bonds of the flex cable to the second IC package at two or more locations.

In aspects of the present disclosure, the end of the flex cable may be connected to the second IC package via tape-automated bonds (TABs) of the flex cable to the second IC package (see, e.g., flex cable 260, TABs 361, and second IC package 120 in FIG. 3C).

According to aspects of the present disclosure, the packaged assembly may include a third IC package disposed above the first IC package (see, e.g., other IC package 130 and first IC package 110 in FIG. 2, above). In some case, the flex cable may not be directly conductively connected to the third IC package. For certain aspects, the third IC package may not be directly conductively connected to the second IC package.

In aspects of the present disclosure, the first IC package may connect to the second IC package via a plurality of electrically conductive connections (see, e.g., first IC package 110, second IC package 120, and solder balls 142 in FIG. 3, above).

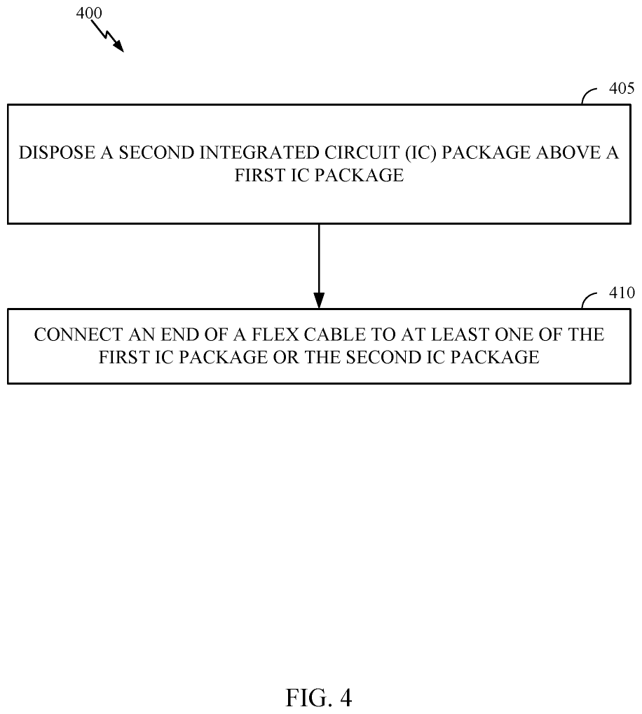

FIG. 4 is a flow diagram illustrating example operations 400 for fabricating a packaged assembly for integrated circuits, in accordance with certain aspects of the present disclosure. The operations 400 may be performed, for example, by an integrated circuit packaging facility.

The operations 400 may begin, at block 405, by disposing a second integrated circuit (IC) package (e.g., second IC package 120) above a first IC package (e.g., first IC package 110).

At block 410, an end of a flex cable (e.g., end 262 of flex cable 260) is connected to at least one of the first IC package or the second IC package. For certain aspects, as described above with respect to FIGS. 3A-D, the flex cable may be connected to the at least one of the first IC package or the second IC package before disposing the second IC package above the first IC package.

According to aspects of the present disclosure, connecting the end of the flex cable to at least one of the first IC package or the second IC package in block 410 as described above may include connecting the end of the flex cable to a bottom of the second IC package (see, e.g., end 262 of flex cable 260 and second IC package 120, described above with reference to FIG. 3C).

In aspects of the present disclosure, connecting the end of the flex cable to at least one of the first IC package or the second IC package in block 410 as described above may include connecting the end of the flex cable to a top of the second IC package (see, e.g., end 262 of flex cable 260 and second IC package 120 described with reference to FIG. 5A, below).

According to aspects of the present disclosure, connecting the end of the flex cable to at least one of the first IC package or the second IC package in block 410 as described above may include connecting the end of the flex cable to a top of the first IC package (see, e.g., end 262 of flex cable 260 and first IC package 110 described with reference to FIG. 5B, below).

In aspects of the present disclosure, connecting the end of the flex cable to at least one of the first IC package or the second IC package in block 410 as described above may include connecting the end of the flex cable to the second IC package via a plurality of electrically conductive connections, wherein the flex cable is not directly conductively connected to the first IC package in the packaged assembly (see, e.g., end 262 of flex cable 260, TABs 361, second IC package 120, and first IC package 110 described with reference to FIG. 3C, above).

According to aspects of the present disclosure, connecting the end of the flex cable to at least one of the first IC package or the second IC package in block 410 as described above may include connecting the end of the flex cable to the second IC package via a plurality of solder on pad (SOP) pads of the second IC package (see, e.g., end 262 of flex cable 260, SOP pads 312, second IC package 120, and first IC package 110 described with reference to FIGS. 3A-D, above). In some such aspects of the present disclosure, the flex cable is not directly conductively connected to the first IC package in the packaged assembly. In this case, operations 400 may include connecting the first IC package to the second IC package via a plurality of electrically conductive connections formed from a plurality of solder balls implemented as a ball grid array (BGA) (see, e.g., second IC package 120, first IC package 110, and solder balls 142 described with reference to FIG. 3D, above).

In aspects of the present disclosure, connecting the end of the flex cable to at least one of the first IC package or the second IC package in block 410 as described above may include connecting the end of the flex cable to a side (e.g., a lateral surface) of the second IC package (see, e.g., end 262 of flex cable 260, lateral surface 602, second IC package 120, and first IC package 110 described with reference to FIG. 6, below).

FIG. 5A is a side view of an exemplary board assembly 500, in accordance with certain aspects of the present disclosure. The board assembly 500 includes several components that are illustrated in the board assemblies 100 and 200 and are not further described in FIG. 5A. In the exemplary board assembly 500, one end 262 of the flex cable 260 is connected to a top of the second IC package 120 via one or more electrically conductive connections. For example, the second IC package may have electrically conductive connections (e.g., SOP pads) exposed through the molding of the second IC package.

FIG. 5B is a side view of an exemplary board assembly 550, in accordance with certain aspects of the present disclosure. The board assembly 550 includes several components that are illustrated in the board assemblies 100 and 200 and are not further described in FIG. 5B. In the exemplary board assembly 550, one end 262 of the flex cable 260 is connected to a top of the first IC package 110 via one or more electrically conductive connections. For example, the first IC package may have electrically conductive connections (e.g., SOP pads) exposed through the molding of the first IC package. In another example, the first IC package may have leads in and/or on the molding (e.g., exposed on at least the top or a lateral surface of the first IC package), which may connect with pins on the bottom of the first IC package.

FIG. 6 is a side view of an exemplary board assembly 600, in accordance with certain aspects of the present disclosure. The board assembly 600 includes several components that are illustrated in the board assemblies 100 and 200 and are not further described in FIG. 6. In the exemplary board assembly 600, one end 262 of the flex cable 260 is connected to a lateral surface 602 of the second IC package 120 via one or more electrically conductive connections. For example, the second IC package may have electrically conductive connections (e.g., SOP pads) exposed through the molding of the second IC package. In another example, the second IC package may have leads in and/or on the molding (e.g., exposed on at least the lateral surface of the second IC package), which may connect with pins on the bottom of the second IC package.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

The various operations of methods described above may be performed by any suitable means capable of performing the corresponding functions. Generally, where there are operations illustrated in figures, those operations may have corresponding counterpart means-plus-function components with similar numbering.

It is to be understood that the claims are not limited to the precise configuration and components illustrated above. Various modifications, changes, and variations may be made in the arrangement, operation, and details of the methods and apparatus described above without departing from the scope of the claims.

1. A packaged assembly for integrated circuits, comprising:
a first integrated circuit (IC) package;
a second IC package disposed above the first IC package; and
a flex cable, wherein an end of the flex cable is connected to at least one of the first IC package or the second IC package.

2. The packaged assembly of claim 1, wherein the end of the flex cable is connected to a bottom of the second IC package.

3. The packaged assembly of claim 1, wherein the end of the flex cable is connected to a top of the second IC package.

4. The packaged assembly of claim 1, wherein the end of the flex cable is connected to a top of the first IC package.

5. The packaged assembly of claim 1, wherein another end of the flex cable remains unconnected in the packaged assembly.

6. The packaged assembly of claim 1, wherein:
the end of the flex cable connects to the second IC package via a plurality of electrically conductive connections; and
the flex cable is not directly conductively connected to the first IC package in the packaged assembly.

7. The packaged assembly of claim 1, wherein:
the end of the flex cable connects to the second IC package via a plurality of solder on pad (SOP) pads of the second IC package;
the flex cable is not directly conductively connected to the first IC package; and
the first IC package is connected to the second IC package via a plurality of electrically conductive connections formed from a plurality of solder balls implemented as a ball grid array (BGA).

8. The packaged assembly of claim 1, wherein the end of the flex cable is connected to a lateral surface of the second IC package.

9. The packaged assembly of claim 1, wherein:
the flex cable connects to a first side of the second IC package; and
a second side of the second IC package is nearer to the first IC package than the first side is to the first IC package.

10. The packaged assembly of claim 1, wherein the end of the flex cable is connected to the second IC package via hot bar bonds of the flex cable to the second IC package at two or more locations.

11. The packaged assembly of claim 1, wherein the end of the flex cable is connected to the second IC package via tape-automated bonds (TABs) of the flex cable to the second IC package.

12. The packaged assembly of claim 1, further comprising:
a third IC package disposed above the first IC package.

13. The packaged assembly of claim 1, wherein the first IC package connects to the second IC package via a plurality of electrically conductive connections.

14. A method for fabricating a packaged assembly for integrated circuits, comprising:
disposing a second integrated circuit (IC) package above a first IC package; and
connecting an end of a flex cable to at least one of the first IC package or the second IC package.

15. The method of claim 14, wherein connecting the end of the flex cable to the at least one of the first IC package or the second IC package comprises connecting the end of the flex cable to a bottom of the second IC package.

16. The method of claim 14, wherein connecting the end of the flex cable to the at least one of the first IC package or the second IC package comprises connecting the end of the flex cable to a top of the second IC package.

17. The method of claim 14, wherein connecting the end of the flex cable to the at least one of the first IC package or the second IC package comprises connecting the end of the flex cable to a top of the first IC package.

18. The method of claim 14, wherein:
connecting the end of the flex cable to the at least one of the first IC package or the second IC package comprises connecting the end of the flex cable to the second IC package via a plurality of electrically conductive connections; and
the flex cable is not directly conductively connected to the first IC package in the packaged assembly.

19. The method of claim 14, wherein:
connecting the end of the flex cable to the at least one of the first IC package or the second IC package comprises connecting the end of the flex cable to the second IC package via a plurality of solder on pad (SOP) pads of the second IC package;
the flex cable is not directly conductively connected to the first IC package in the packaged assembly; and
the method further comprises connecting the first IC package to the second IC package via a plurality of electrically conductive connections formed from a plurality of solder balls implemented as a ball grid array (BGA).

20. The method of claim 14, wherein connecting the end of the flex cable to the at least one of the first IC package or the second IC package comprises connecting the end of the flex cable to a lateral surface of the second IC package.
